(19) United States
(12) Patent Application Publication
(10) Pub. No.: US 2025/0008688 A1
(43) Pub. Date: Jan. 2, 2025

(54) System and Method for Rear-Door Cooling Units

(71) Applicant: Hoffman Enclosures Inc., Anoka, MN (US)

(72) Inventors: Stefan Djuranec, Höfen (DE); Matthew R. Archibald, Derry, NH (US); Hans-Jörg Weiler, Ettlingen (DE); Christophe Marcinkowski, Betschdorf (FR)

(21) Appl. No.: 18/760,527

(22) Filed: Jul. 1, 2024

Related U.S. Application Data
(60) Provisional application No. 63/511,501, filed on Jun. 30, 2023.

(51) Int. Cl. H05K 7/20

(52) U.S. Cl. CPC H05K 7/20263; H05K 7/20172; H05K 7/20209

(57) ABSTRACT

Embodiments of the present disclosure provide a cooling system for electrical equipment. The cooling system includes a rack, a rear-door cooling unit, a liquid-to-air heat exchanger, a fan, a controller, and a power supply unit. The rear-door cooling unit is mounted to the rack, and is pivotable about a first axis between an open position and a closed position. The rear-door cooling unit defines a first side proximate the rack, and a second side opposite the first side. The liquid-to-air heat exchanger is mounted within the rear-door cooling unit. The fan, the controller, and the power supply unit are mounted to the rear-door cooling unit at the second side, and are accessible from the second side when the rear-door cooling unit is in the closed position.

### CROSS-REFERENCE TO RELATED APPLICATIONS

This application claims priority to U.S. Provisional Patent Application No. 63/511,501 filed Jun. 30, 2023, the entirety of which is incorporated by reference.

### BACKGROUND

Cooling systems can be provided for electrical components in data centers. In some cases, equipment in a data center can be cooled through various means, including through liquid-based cooling systems, air-based cooling systems, or combinations thereof. Electrical equipment within a data center can be housed in racks and can include piping and manifolds for receiving a liquid coolant pumped through a liquid cooling circuit. The liquid coolant can be delivered to components of electrical equipment to provide a heat transfer from those components to the heat of the liquid coolant.

### SUMMARY

Embodiments of the present disclosure can provide a cooling system for electrical equipment. The cooling system can include a rack, a rear-door cooling unit, a liquid-to-air heat exchanger, a fan, a controller, and a power supply unit. The rear-door cooling unit can be mounted to the rack, and can be pivotable about a first axis between an open position and a closed position. The rear-door cooling unit can define a first side proximate the rack, and a second side opposite the first side. The liquid-to-air heat exchanger can be mounted within the rear-door cooling unit. The fan, the controller, and the power supply unit, can be mounted to the rear-door cooling unit at the second side, and can be accessible from the second side when the rear-door cooling unit is in the closed position.

In some embodiments, each of the fan, the controller, and the power supply unit can be configured for tool less removal. In some embodiments, each of the fan, the controller, and the power supply unit includes a blind mate connector that engages a corresponding blind mate connector of the rear-door cooling unit. In some embodiments, the rear-door cooling unit can include a hinge at a first lateral side of the rear-door cooling unit, the hinge at least partially defining the first axis. In some embodiments, the liquid-to-air heat exchanger can include a supply header and a return header, wherein each of the supply header and the return header are positioned at a second lateral side of the rear-door cooling unit, opposite the first lateral side, each of the supply header and the return header including a quick disconnect fitting. In some embodiments, the rear-door cooling unit includes apertures configured to receive hosing in a bottom feed configuration. In some embodiments, the power supply unit is one of a plurality of power supply units. In some embodiments, the fan is one of a plurality of fans, each of the plurality of fans mounted to the rear-door cooling unit at the second side. In some embodiments, each of the fan, the controller, and the power supply unit are hot swappable. In some embodiments, a second axis extends through the first side and the second side, and a maximum depth of the rear-door cooling unit in a direction parallel to the second axis is between about 200 mm and about 250 mm. In some embodiments, a lateral axis is defined between opposing lateral sides of the rear-door cooling unit, wherein the controller is configured for removal from the rear-door cooling unit in a direction parallel to the lateral axis. In some embodiments, the power supply unit is configured for removal from the rear-door cooling unit in a direction parallel to the lateral axis.

Embodiments of the present disclosure can provide a cooling system including a rear-door cooling unit. The rear-door cooling unit can include a first lateral portion including a first lateral surface. A second lateral portion can be opposite the first lateral portion, the second lateral portion including a second lateral surface, the second lateral surface being parallel to the first lateral surface and a lateral axis being defined between the first lateral surface and the second lateral surface. A heat exchanger can include a supply port and a return port, both of the supply port and the return port positioned within the second lateral portion. A fan assembly can define a fan rotation axis, the fan rotation axis being perpendicular to the lateral axis. A removable controller can be insertable into the rear-door cooling system in an insertion direction that is parallel to the lateral axis. A first power supply unit can be insertable into the rear-door cooling unit in a direction that is parallel to the lateral axis.

In some embodiments, the rear-door cooling unit defines an internal portion and an external portion opposite the internal portion, wherein each of the fan assembly, the removable controller, and the power supply unit is mounted at the external portion. In some embodiments, the cooling system further comprises a rack, and the rear-door cooling unit is mounted to the rack, with the internal portion facing the rack, and the external portion facing away from the rack. In some embodiments, the rear-door cooling unit is configured to rotate relative to the rack between an open position and a closed position, wherein the fan assembly, the removable controller, and the power supply unit are accessible from an exterior of the rack in both of the open and closed position. In some embodiments, a depth direction is perpendicular to the lateral axis, wherein a maximum depth of the rear-door cooling unit is between about 200 mm and about 250 mm. In some embodiments the cooling system further comprises a second power supply unit, wherein the first and second power supply units are configured for tool less removal from the rear-door cooling unit. In some embodiments the removable controller is configured for tool less removal from the rear-door cooling unit.

Embodiments of the present disclosure can provide a method of cooling electrical equipment. A rack can be provided, and a rear-door cooling unit can be mounted to the rack, the rear-door cooling unit being pivotable about a first axis between an open position and a closed position and defining a first side proximate the rack, and a second side opposite the first side. A liquid-to-air heat exchanger can be mounted within the rear-door cooling unit. A fan, a controller, and a power supply unit can be mounted into the rear-door cooling unit, each of the fan, the controller, and the power supply unit mounted to the rear-door cooling unit at the second side, and accessible from the second side when the rear-door cooling unit is in the closed position. A flow control valve can be operated to allow a flow of fluid through the liquid-to-air heat exchanger. The fan can be operated to produce an air flow across the heat exchanger.

### BRIEF DESCRIPTION OF THE DRAWINGS

The accompanying drawings, which are incorporated in and form a part of this specification, illustrate embodiments of the invention and, together with the description, serve to explain the principles of embodiments of the invention:

FIG. 1 is a schematic of a rear-door cooling unit, according to an embodiment of the invention;

FIG. 2 is a front, right isometric view of a rear-door cooling unit, according to an embodiment of the invention;

FIG. 3 is a front, right isometric view of a rear-door cooling unit, according to an embodiment of the invention;

FIG. 4 is a front, right isometric view of a rear-door cooling unit mounted onto an enclosure frame, according to some embodiments;

FIG. 5 is a right elevation view of the rear-door cooling unit of FIG. 3;

FIG. 6 is a front elevation view of the rear-door cooling unit of FIG. 3;

FIG. 7 is a top plan view of a row of three rear-door cooling units;

FIG. 8 is a bottom plan view of the rear-door cooling unit of FIG. 3;

FIG. 9 is a partial bottom view of the rear-door cooling unit of FIG. 3;

FIG. 10 is a partial top view of the rear-door cooling unit of FIG. 3;

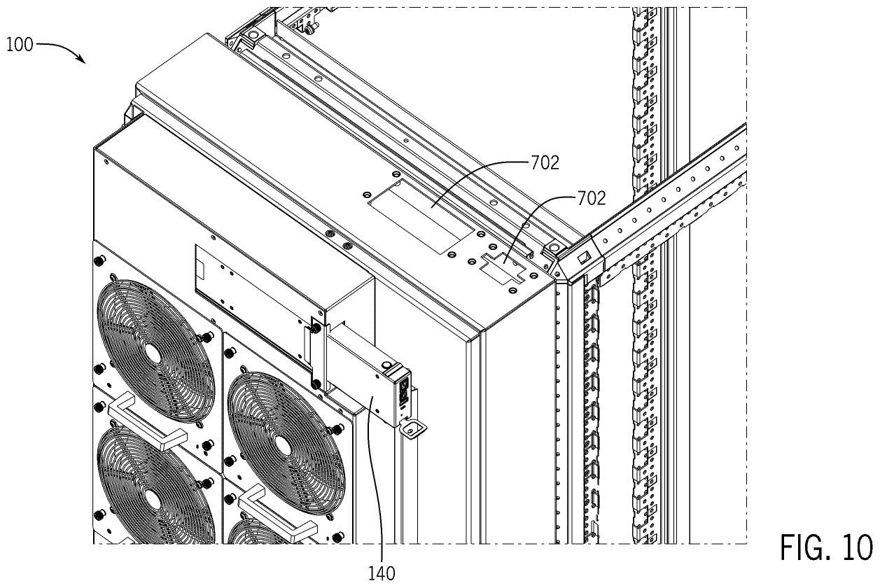

FIG. 11 is an isometric view of a hot-swappable controller usable with the rear-door cooling unit of FIG. 3;

FIG. 12 is a rear isometric view of the rear-door cooling unit of FIG. 3, showing a heat exchanger of the rear-door cooling unit;

FIG. 13 is a partial bottom view of the rear-door cooling unit of FIG. 3 showing flexible hosing in a bottom of the rear-door cooling unit;

FIG. 14 is a partial bottom view of the rear-door cooling unit of FIG. 3 with the flexible hosing removed to show power inlet for the power supply units; and

FIG. 15 is a system schematic showing a controller, fan module, and sensing components of a rear-door cooling unit.

FIG. 16 is a rear isometric view of the rear-door cooling unit of FIG. 3, with paneling removed to show the heat exchanger and headers of the rear-door cooling unit.

### DETAILED DESCRIPTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

Also as used herein, unless otherwise limited or defined, “or” indicates a non-exclusive list of components or operations that can be present in any variety of combinations, rather than an exclusive list of components that can be present only as alternatives to each other. For example, a list of “A, B, or C” indicates options of: A; B; C; A and B; A and C; B and C; and A, B, and C. Correspondingly, the term “or” as used herein is intended to indicate exclusive alternatives only when preceded by terms of exclusivity, such as “either,” “one of,” “only one of,” or “exactly one of.” For example, a list of “one of A, B, or C” indicates options of: A, but not B and C; B, but not A and C; and C, but not A and B. A list preceded by “one or more” (and variations thereon) and including “or” to separate listed elements indicates options of one or more of any or all of the listed elements. For example, the phrases “one or more of A, B, or C” and “at least one of A, B, or C” indicate options of: one or more A; one or more B; one or more C; one or more A and one or more B; one or more B and one or more C; one or more A and one or more C; and one or more of A, one or more of B, and one or more of C. Similarly, a list preceded by “a plurality of” (and variations thereon) and including “or” to separate listed elements indicates options of multiple instances of any or all of the listed elements. For example, the phrases “a plurality of A, B, or C” and “two or more of A, B, or C” indicate options of: A and B; B and C; A and C; and A, B, and C.

In some implementations, devices or systems disclosed herein can be utilized, manufactured, installed, etc. using methods embodying aspects of the invention. Correspondingly, any description herein of particular features, capabilities, or intended purposes of a device or system is generally intended to include disclosure of a method of using such devices for the intended purposes, of a method of otherwise implementing such capabilities, of a method of manufacturing relevant components of such a device or system (or the device or system as a whole), and of a method of installing disclosed (or otherwise known) components to support such purposes or capabilities. Similarly, unless otherwise indicated or limited, discussion herein of any method of manufacturing or using for a particular device or system, including installing the device or system, is intended to inherently include disclosure, as embodiments of the invention, of the utilized features and implemented capabilities of such device or system.

In some embodiments, aspects of the invention, including computerized implementations of methods according to the invention, can be implemented as a system, method, apparatus, or article of manufacture using standard programming or engineering techniques to produce software, firmware, hardware, or any combination thereof to control a processor device (e.g., a serial or parallel general purpose or specialized processor chip, a single- or multi-core chip, a microprocessor, a field programmable gate array, any variety of combinations of a control unit, arithmetic logic unit, and processor register, and so on), a computer (e.g., a processor device operatively coupled to a memory), or another electronically operated controller to implement aspects detailed herein. Accordingly, for example, embodiments of the invention can be implemented as a set of instructions, tangibly embodied on a non-transitory computer-readable media, such that a processor device can implement the instructions based upon reading the instructions from the computer-readable media. Some embodiments of the invention can include (or utilize) a control device such as an automation device, a special purpose or general-purpose computer including various computer hardware, software, firmware, and so on, consistent with the discussion below. As specific examples, a control device can include a processor, a microcontroller, a field-programmable gate array, a programmable logic controller, logic gates etc., and other typical components that are known in the art for implementation of appropriate functionality (e.g., memory, communication systems, power sources, user interfaces and other inputs, etc.). In some embodiments, a control device can include a centralized hub controller that receives, processes and (re) transmits control signals and other data to and from other distributed control devices (e.g., an engine controller, an implement controller, a drive controller, etc.), including as part of a hub-and-spoke architecture or otherwise.

The term “article of manufacture” as used herein is intended to encompass a computer program accessible from any computer-readable device, carrier (e.g., non-transitory signals), or media (e.g., non-transitory media). For example, computer-readable media can include but are not limited to magnetic storage devices (e.g., hard disk, floppy disk, magnetic strips, and so on), optical disks (e.g., compact disk (CD), digital versatile disk (DVD), and so on), smart cards, and flash memory devices (e.g., card, stick, and so on). Additionally, it should be appreciated that a carrier wave can be employed to carry computer-readable electronic data such as those used in transmitting and receiving electronic mail or in accessing a network such as the Internet or a local area network (LAN). Those skilled in the art will recognize that many modifications may be made to these configurations without departing from the scope or spirit of the claimed subject matter.

Certain operations of methods according to the invention, or of systems executing those methods, may be represented schematically in the FIGS. or otherwise discussed herein. Unless otherwise specified or limited, representation in the FIGS. of particular operations in particular spatial order may not necessarily require those operations to be executed in a particular sequence corresponding to the particular spatial order. Correspondingly, certain operations represented in the FIGS., or otherwise disclosed herein, can be executed in different orders than are expressly illustrated or described, as appropriate for particular embodiments of the invention. Further, in some embodiments, certain operations can be executed in parallel, including by dedicated parallel processing devices, or separate computing devices configured to interoperate as part of a large system.

As used herein in the context of computer implementation, unless otherwise specified or limited, the terms “component,” “system,” “module,” “block,” and the like are intended to encompass part or all of computer-related systems that include hardware, software, a combination of hardware and software, or software in execution. For example, a component may be, but is not limited to being, a processor device, a process being executed (or executable) by a processor device, an object, an executable, a thread of execution, a computer program, or a computer. By way of illustration, both an application running on a computer and the computer can be a component. One or more components (or system, module, and so on) may reside within a process or thread of execution, may be localized on one computer, may be distributed between two or more computers or other processor devices, or may be included within another component (or system, module, and so on).

Also as used herein, unless otherwise limited or defined, the terms “about,” “substantially,” and “approximately” refer to a range of values±5% of the numeric value that the term precedes. As a default the terms “about” and “approximately” are inclusive to the endpoints of the relevant range, but disclosure of ranges exclusive to the endpoints is also intended.

Also as used herein, unless otherwise limited or defined, “integral” and derivatives thereof (e.g., “integrally”) describe elements that are manufacture as a single piece without fasteners, adhesive, or the like to secure separate components together. For example, an element stamped as a single-piece component from a single piece of sheet metal, without rivets, screws, or adhesive to hold separately formed pieces together is an integral (and integrally formed) element. In contrast, an element formed from multiple pieces that are separately formed initially then later connected together, is not an integral (or integrally formed) element.

Also as used herein, unless otherwise defined or limited, the term “lateral” refers to a direction that does not extend in parallel with a reference direction. A feature that extends in a lateral direction relative to a reference direction thus extends in a direction, at least a component of which is not parallel to the reference direction. In some cases, a lateral direction can be a radial or other perpendicular direction relative to a reference direction.

The following discussion is presented to enable a person skilled in the art to make and use embodiments of the invention. Various modifications to the illustrated embodiments will be readily apparent to those skilled in the art, and the generic principles herein can be applied to other embodiments and applications without departing from embodiments of the invention. Thus, embodiments of the invention are not intended to be limited to embodiments shown but are to be accorded the widest scope consistent with the principles and features disclosed herein. The following detailed description is to be read with reference to the figures, in which like elements in different figures have like reference numerals. The figures, which are not necessarily to scale, depict selected embodiments and are not intended to limit the scope of embodiments of the invention. Skilled artisans will recognize the examples provided herein have many useful alternatives and fall within the scope of embodiments of the invention.

Cooling systems can be provided for data centers to cool electrical components within a data center. During operation, electrical components, typically housed in racks having a standard rack footprint (e.g., a standard height, width, and depth), generate heat. As that heat may degrade electrical components, damage the systems, or degrade performance of the components, cooling systems can be provided for data centers for transferring heat away from racks of the data center with electrical components that need to be cooled.

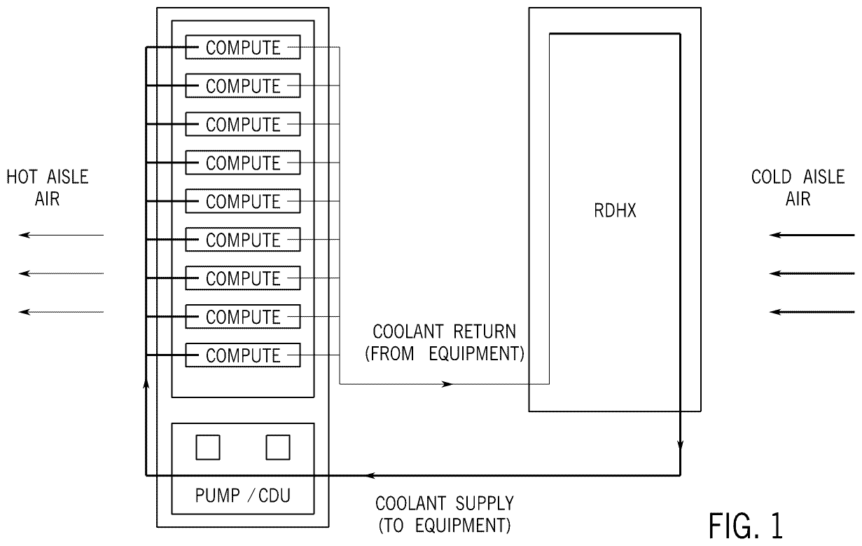

Cabinets or racks containing electrical equipment are typically arranged in rows within a data center, defining aisles between consecutive rows. Racks can be pre-assembled and “rolled in” to a space in the row adjacent to other racks, the space being pre-defined to have the footprint of a standard rack. This arrangement allows a modular construction of or addition to components in a data center. In some configurations, aisles on opposite sides of a rock of cabinets can be alternately designated as a cold aisle, or a hot aisle, and heat generated by the electrical components of a cabinet can be expelled to the hot air aisle, as shown in FIG. 1. In some cases, a side of a rack facing a hot aisle can be referred to as a rear side, and a side of a rack facing a cold aisle can be referred to as a front side.

FIG. 1 illustrates a schematic for a rear-door cooling unit, according to some embodiments of the invention. In the illustrated embodiment, a rack of electrical equipment is shown on the left, and a rear-door cooling unit is shown in the right. The rack of electrical equipment includes a plurality of compute nodes (e.g., servers) and a coolant distribution unit (“CDU”). A coolant (e.g., water, a water glycol mixture, propylene, a dielectric fluid, etc.) can flow through the compute nodes to cool the nodes through a transfer of waste heat from the nodes to the coolant. The CDU can include a pump to pump the coolant through the compute nodes. As shown, a heated coolant can flow from the compute nodes (e.g., via one or more manifolds) to the rear door cooling unit. The rear door cooling unit can include a heat exchanger (“RDHX”) to allow a transfer of heat from the coolant into an ambient air. As further shown in FIG. 1, air from the cold aisle can flow across the RDHX to transfer heat from the coolant to the air, and the cooled coolant can return to the rack to further cool the compute nodes. In some cases, including the examples described below, a rear-door cooling unit can be mounted at a rear of a rack, facing a hot aisle, and the rear door cooling unit can include fans to draw air from the cold aisle across the rack, and blow the air towards the hot aisle. In some cases, a cooling unit can be mounted at a front of a rack, facing a cold aisle. In the illustrated example, the rear-door cooling unit is a liquid-to-air cooling unit. In other examples, a rear-door cooling unit can be an air-to-liquid cooling unit, or a liquid-to-liquid cooling unit.

In some cases, cooling systems (e.g., rear-door cooling units, coolant distribution units, heat exchangers, pumping units, etc.) can impact an uptime of electrical equipment within a data center. For example, a failure in a cooling system can require that electrical equipment cooled by the cooling system be shut down until cooling can be restored, to prevent overheating of the electrical equipment. It can be advantageous to provide cooling systems (e.g., rear-door cooling units) that can be resilient to component failures, so that failure of a component of the cooling system does not produce a failure of the cooling system and consequent downtime or degrading of the cooled electrical equipment. In some cases, some components of a cooling system can be redundant, and upon removing the component, the cooling system can fail over to a backup component. For example, according to some embodiments, as discussed below, power supply units of a rear-door cooling unit can be redundant, and a rear-door cooling unit can be provided with two or more power supply units. The power supply units can be configured to operate in parallel (e.g., two or more power supply units can operate at the same time), in primary-backup configurations, or in other power supply arrangements. Upon failure or removal of one power supply unit, then, the remaining one or more power supply units can operate to provide power to the electrical components of the rear-door cooling unit. In some cases, other components of a rear-door cooling unit can be redundant, or otherwise resilient to failure of a single component, including fans, control units, filtration systems, fluid flow paths, etc.

According to some embodiments, cooling systems for cooling electrical equipment within a data center can also include features and systems for toolless removal and installation of components, to increase an case of maintenance of the system. For example, electrical components of a rear-door cooling unit, including fans, power supply units, controllers, pumps, condensate pumps, leak detection systems, sensing components (e.g., fluid flow sensors, temperature sensors, pressure sensors, humidity sensors, etc.) can include blind mate connections that correspond to blind mate connections of the rear-door cooling unit to provide electrical connectivity and communication without the need for manual connection of electrical components. In some cases, fasteners for securing components (e.g., fans) to the rear-door cooling unit can be engages without tools for installation and removal of fans. For example, thumb screws can be used to secure fans (e.g., fan assemblies) to the rear-door cooling unit. In some cases, fluid flow components can also include systems for toolless maintenance. For example, liquid connections can use quick-connect fittings.

In some cases, opening a rear-door cooling unit can produce an interruption in cooling of electrical equipment. For example, when a rear-door cooling unit is opened (e.g., is rotated about a hinge into an open position), air from a hot aisle can be drawn across a liquid-to-air heat exchanger which can reduce a cooling, or, in some cases, can reverse a direction of heat transfer (e.g., hot air can heat the coolant flowing through the cooling unit). Some conventional rear-door cooling units can require opening the rear door to access the components to be maintained. Example of the rear-door cooling unit described herein can provide advantages over conventional cooling systems by providing access to components to be maintained from an exterior of the unit, without requiring interruption to cooling of the electrical equipment to access the components.

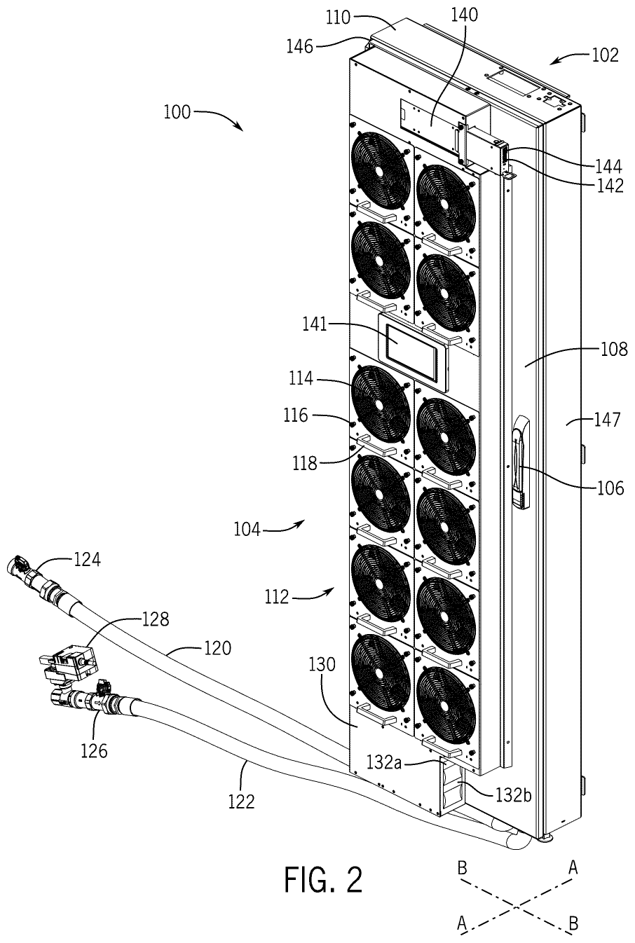

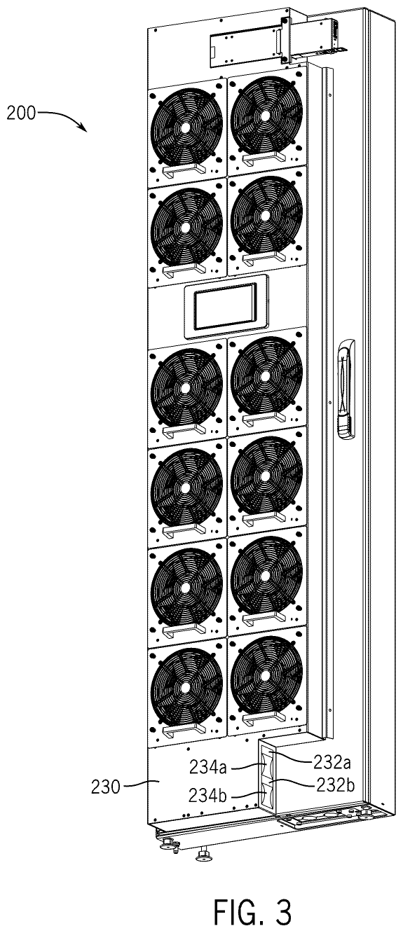

FIG. 2 illustrates an example of a rear-door cooling unit 100, according to some aspects of the present disclosure. The rear-door cooling unit can define an internal portion 102 (e.g., a rack-facing portion at a rack-facing side of the rear-door cooling unit) configured to be proximate to a rack of electrical equipment when the rear-door cooling unit 100 is mounted to the rack (e.g., as shown in FIG. 3). An external portion 104 (e.g., an aisle-facing portion at an aisle-facing side of the rear-door cooling unit) can be opposite the internal portion 102 (e.g., in a direction further from the rack to which the rear-door cooling unit 100 is mounted than the internal portion 102), and can face an aisle within a data center (e.g., a cold aisle or a hot aisle, as shown in FIG. 1). A depth direction can be defined between the internal portion 102 and the external portion 104, parallel to axis A. The external portion 104 can be accessible from an aisle of the data center, and an operator of the rear-door cooling unit 100 can access components of the rear-door cooling unit 100 positioned along the external portion 104 for maintenance without opening the rear-door cooling unit 100. In some embodiments, as illustrated, a handle 106 can be provided on a first lateral side 108 of the rear-door cooling unit 100, and a hinge side 110 of the rear-door cooling unit 100 can be laterally opposite the first lateral side 108. An operator can engage the handle 106 to open the rear-door cooling unit 100 (e.g., produce an angular rotation about an axis positioned along the hinge side 110) and provide access to the internal side 102 and equipment within the rack to which the rear-door cooling unit 100 is mounted. A lateral surface 146 of the rear-door cooling unit can be defined at the hinge side 110, and a lateral surface 147 can be defined at the first lateral side 108. The lateral surfaces 146, 147 can define the lateral limits of the rear-door (e.g., a total width of the rear-door cooling unit 100 can be defined between the lateral surfaces 146, 147. Further, the lateral surfaces 146, 147 can be parallel, and a lateral axis (e.g., parallel to axis B) can be defined between and normal to the surfaces 146, 147.

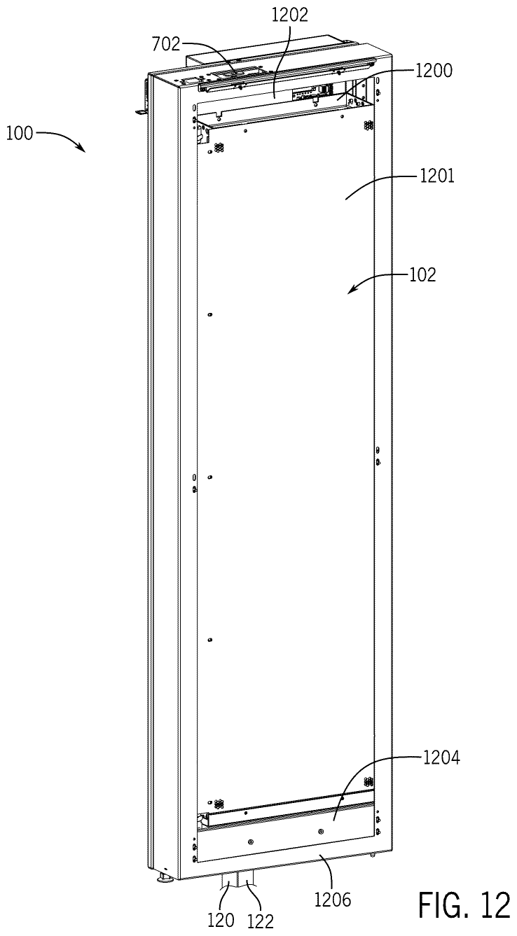

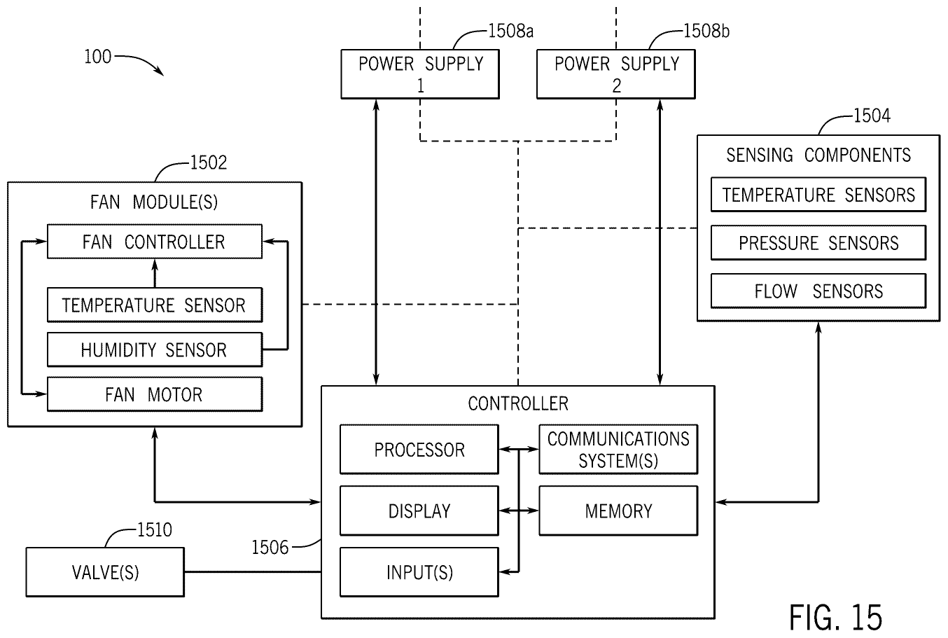

As further shown in FIG. 2, the rear-door cooling unit 100 can include a fan bank 112 with a plurality of fan assemblies 114 to induce air flow across a liquid-to-air heat exchanger (e.g., heat exchanger 1200 shown in FIG. 12) to cool electrical equipment in a rack. In the illustrated embodiment, the fan assemblies 114 are arranged in two columns and 6 rows, and the fan bank 112 includes 12 fan assemblies 114. In other embodiments, more or fewer columns of fan assemblies can be provided for a rear-door cooling unit including one column, three columns, four columns, etc. In some cases, a fan bank 112 can include more or fewer rows of fan assemblies, which can correlate to a height of a rear-door cooling unit. In some cases, a fan bank can include fan panels, each panel being separately maintainable (e.g., removable or installable) and can each include a plurality of fans. Each fan assembly 114 can define a rotation axis that can be parallel to an air flow through the fan, and parallel to axis A. In some cases, as discussed further with respect to FIG. 15, the fan assemblies 114 can include fan motors, one or more sensors, and a fan controller, and can be controllable to produce a set amount of air flow across the liquid-to-air heat exchanger for a desired heat transfer rate. In some cases, the fan assemblies can include fans with a DC operating voltage of 48 V.

As illustrated, the fan assemblies 114 can be accessible from an aisle of a data center, and can be serviced (e.g., removed, installed, etc.) without a need to open the rear-door cooling unit 100 or otherwise remove a casing, housing, etc. Fan assemblies 114 can be hot-swappable, and can be removed, replaced, or installed without the need to interrupt an operation of the rear-door cooling unit 100 (e.g., by opening the rear-door cooling unit) or electrical equipment cooled by the rear-door cooling unit. In some examples, when a fan assembly 114 is removed, the other fan assemblies continue operation to produce an airflow across the liquid-to-air heat exchanger. In some cases, when one or more fan assemblies 114 are removed from the rear-door-cooling unit 100, the remaining fan assemblies 114 can increase a speed of the fans of the fan assemblies 114 to maintain a set air flow rate. Fan assemblies of a rear-door cooling unit can include features to allow a toolless removal and installation of the fan assemblies. For example, as illustrated, the fan assemblies 114 can be secured to the rear-door cooling unit 100 with the use of thumb screws 116, which can be manually tightened or loosened (e.g., removed) by an operator without the need for tools. Additionally, fan assemblies 114 can each include one or more handles 118 which can provide a gripping location for an operator to engage the fan assembly 114 to pull the fan assembly 114 from the rear-door cooling unit 100 and to grip the fan assembly 114. The fan assemblies 114 can include blind mate connections (not shown) in a rear portion thereof, which can engage (e.g., contact, or matingly engage) corresponding blind mate connections of the rear-door cooling unit 100 to electrically connect the fan assemblies 114 and the rear-door cooling unit 100.

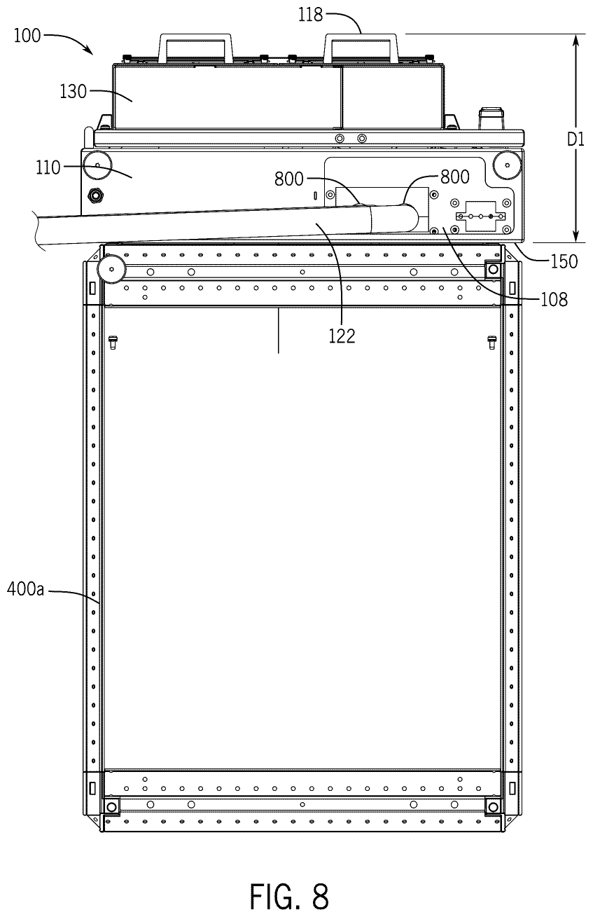

A rear-door cooling unit can include piping components to fluidly connect the rear-door cooling unit (e.g., a liquid-to-air heat exchanger of the rear-door cooling unit) with a fluid cooling circuit for a rack of electrical equipment. For example, a rear-door cooling unit can include hosing and piping for a return line to allow heated fluid to flow into a liquid-to-air heat exchanger of the rear-door cooling unit, and a hosing and piping of a supply line to provide cooled liquid from the rear-door cooling unit to the electrical equipment to be cooled (e.g., as illustrated in FIG. 1). In this regard, FIG. 2 further illustrates return line hosing 120 for heated fluid to enter the rear-door cooling unit 100 and supply line hosing 122 for cooled fluid to exit the rear-door cooling unit 100 to the electrical equipment to be cooled. In the illustrated embodiment, the return line hosing 120 and the supply line hosing 122 are shown in a bottom feed configuration (e.g., entering the rear-door cooling unit 100 at a bottom thereof). In some examples, hosing can enter the rear-door cooling unit 100 in a top-feed configuration (e.g., at a top of the unit 100). As shown in FIG. 8, the hosing 120, 122 can enter the rear-door cooling unit 100 at bottom feed apertures 800 defined in the first lateral side 108 of the unit 100.

As further shown in FIG. 2, the hosing 120, 122 can include quick-connect fittings 124, 126 respectively, to allow a toolless and substantially leak-free connection and disconnection to fluid circuits of electrical equipment to be cooled (e.g., to manifolds, other hosing, in-row cooling circuits, pumping units, filtration systems, etc.). As described further below, the hosing 120, 122 can further include quick disconnect fittings to connect to corresponding fittings of a return header and a supply header of a heat exchanger of the rear-door cooling unit 100. In some cases, sensors can be provided along one or both of supply line 122 and return line hosing 120 to measure parameters (e.g., temperature, pressure, flow rate, etc.) of the fluid in the supply or return line hosing 122, 120.

In some cases, valves can be provided along a fluid flow path for fluid of a rear-door cooling unit (e.g., rear-door cooling unit) to allow, control, or halt fluid flow through the unit. As shown, the rear-door cooling unit 100 can include a valve 128 to control a flow of fluid through the rear-door cooling unit 100. In the illustrated example, the valve is fluidly connected to the supply line 122 of the rear-door cooling unit 100. In some examples, a valve can be housed within a rear-door cooling unit, or can be fluidly connected to a return line hosing. In some examples, valves can be housed in CDUs to control flow through a rear-door cooling unit. As shown, the valve 128 that is electronically controlled or actuated (e.g., the valve comprises a servo motor, linear actuator, or other flow control mechanism that is electronically controllable). The valve 128 can be selectively controlled to achieve a desired flow rate of fluid, to stop the flow of fluid, or to allow all fluid flow through the rear-door cooling unit 100. In some cases, a flow control valve of a rear-door cooling unit can be manually controlled. In the illustrated example, the valve 128 is a two-way valve. In other examples, a valve of a rear-door cooling unit can be a three-way valve. For example, in some cases, a bypass line can be provided between a supply line (e.g., hosing of a supply line) and a return line (e.g., hosing of a return line). A three-way valve can control a proportion of coolant that flow through a heat exchanger, and a proportion that flows through a bypass line (e.g., directly from the return line to the supply line, bypassing the heat exchanged) to achieve desired operational characteristics.

Rear-door cooling units can include power supply units for providing power to electronic components of the unit. For example, the electronic components of a rear-door cooling unit can require 48 V DC while a power provided from a facility can be provided as AC voltage. In some cases, power supply units of a rear-door cooling unit can transform an AC voltage (e.g., a single phase or multi-phase AC voltage) from a facility to a DC voltage to power the electrical components of the rear-door cooling unit. As illustrated in FIG. 2, the rear-door cooling unit 100 can include a power supply housing 130 arranged at a bottom of the unit 100. Arranging a power supply housing in a bottom of a rear-door cooling unit can be advantageous when the rear-door cooling unit is installed in a bottom feed configuration, as it can allow for electrical connection to the power supply housing from a facility with minimal length of electrical cord. The housing 130 can house one or more power supply units 132. In the illustrated embodiment, the rear-door cooling unit 100 include two power supply units 132a, 132b within the housing, the power supply unit 132a positioned vertically above the power supply unit 132b. In other embodiments, a rear-door cooling unit can include only one power supply unit, or more than two power supply units. The power supply units 132a, 132b are each configured to receive an AC voltage and output a 48V DC signal. In some case, power supply units can be configured to transform an AC voltage to produce a signal with any desired voltage and current. In some cases, a power supply housing can be positioned at a top of a rear-door cooling unit, or centrally to a rear-door cooling unit.

The power supply units 132a, 132b can be redundant power supply units, and the rear-door cooling unit 100 can operate with at least one of the power supply units 132a, 132b in operation (e.g., the power supply units 132a, 132b can be hot-swappable). If one of the power supply units 132a, 132b fails, the other of the power supply units 132a, 132b can provide power to all of the electrical components of the rear-door cooling unit. In some cases, the power supply units 132a, 132b can be operated in active-active mode with both operating in parallel to provide power to the rear-door cooling unit 100. In some cases, the power supply units 132a, 132b can be operated in active-passive mode with only one of the power supply units 132a, 132b in operation at a given instance of time. In some cases, a control system of the rear-door cooling unit 100 can alternate the active power supply periodically to equalize a wear on the power supply units 132a, 132b. In some cases, the power supply units can be operated in active-standby mode, with a first of the power supply units 132a, 132b being a primary power supply unit and a second of the power supply units 132a, 132b being a secondary power supply unit. In active-standby mode, the primary power supply unit can be the default operational power supply unit, and the secondary power supply unit can be inactive until the primary power supply unit is not in operation (e.g., upon failure or removal of the primary power supply unit). In some cases, power supply units can be provided to achieve standards for redundancy and resiliency. For example, power supply units of a rear-door cooling unit can be provided for N+1 redundancy, 1+1 redundancy, 2+1 redundancy, 3+1 redundancy, etc.

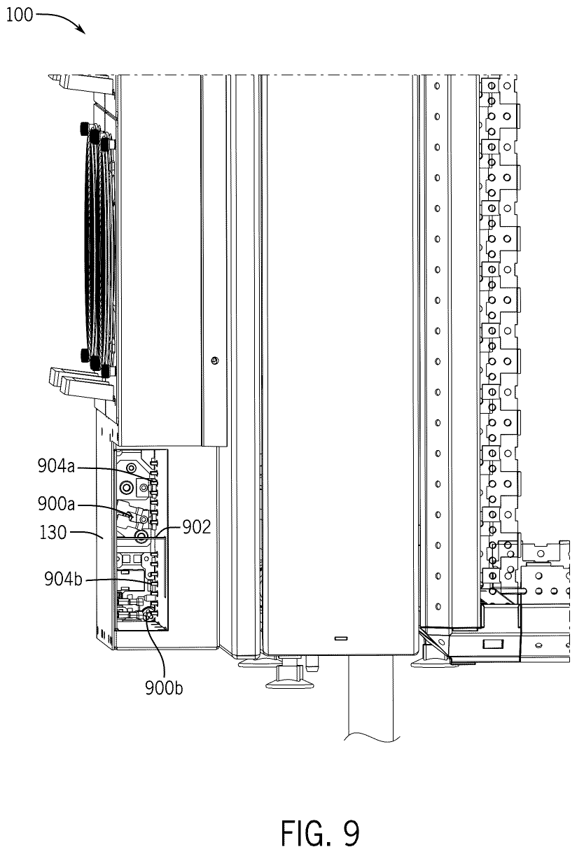

As shown in FIG. 2, the power supply units 132a, 132b can be positioned along the external portion 104 (e.g., at an aisle-facing side) of the rear-door cooling unit 100, and can be accessible to an operator from an aisle of the data center without opening the rear-door cooling unit 100 (e.g., without interrupting an operation of the rear-door cooling unit 100). The power supply units 132a, 132b can include blind mate connections (not shown) to interface with electrical and mechanical connections of the rear-door cooling unit 100 (e.g., as illustrated in FIG. 9). In some cases, the power supply units can be inserted and removed from the housing 130 in a lateral direction that is parallel to axis B (e.g., perpendicular to rotational axes of the fans of the fan assemblies 114). As discussed further below, this arrangement can advantageously reduce a clearance required (e.g., a total depth required for installation and maintenance of the rear-door cooling unit 100 in a depth direction parallel to axis A) for the rear-door cooling unit 100. In some embodiments, power supply units of rear-door cooling units can include handles to allow an operator to grip the power supply unit to pull the power supply unit our of the housing. In this regard, FIG. 3 illustrates a rear-door cooling unit 200 with a housing 230 including two power supply units 232a, 232b, which can be similar to power supply units 132a, 132b. As shown in FIG. 3, the power supply units 232a, 232b can include handles 234a, 234b to provide a contact and gripping location to engage the respective power supply unit 232a, 232b.

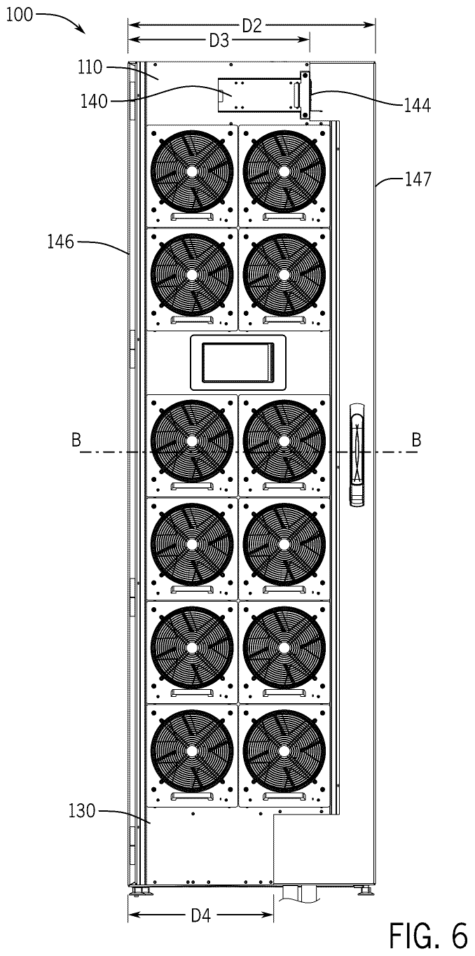

Returning to FIG. 2, a controller 140 can be provided for the rear-door cooling unit 100 to implement control systems and methods for the rear-door cooling unit 100. For example, the controller can be configured to control one or more fan speed of the fans in the fan assemblies 114 to achieve a desired heat transfer rate. In some cases, the controller can implement proportional integral derivative (PID) controllers to adjust one or both of fan speed and a flow rate of fluid through the liquid-to-air heat exchanger (e.g., through control of the valve 128) to achieve a set point for one or more target parameters (e.g., air or fluid temperature, air or fluid temperature differentials, pressure drop, air flow rate, etc.). The controller 140 can be hot-swappable, and can be removed from the rear-door cooling unit 100 without causing an interruption in cooling of the electrical equipment. As shown, the controller 140 is accessible from the external side 104 of the rear-door cooling unit 100, and removal, installation, and replacement of the controller 140 can be performed without opening the rear-door cooling unit 100. In some cases, if the controller 140 fails or is removed from operation, electronic components (e.g., fans assemblies 114, flow control components such as valve 128, power supply units 132a, 132b, etc.) can operate at default speeds (e.g., the last known speed, or a hardcoded default speed) until the controller 140 is replaced or is operational. In some cases, electrical components of a rear-door cooling unit can include local controllers, and local controllers can operate the components in an autonomous mode until a connection is established with a main controller (e.g., controller 140). As shown, the controller 140 can be removed or installed in a lateral direction, parallel to axis B (e.g., similar to the power supply units 132a, 132b). The controller 140 can include one or more retention mechanisms, which can be disengaged by displacing a handle 142 of the controller 140 to allow removal of the controller 140. In some embodiments, the controller 140 can define a front surface 144 that is perpendicular to the axis B. In some cases, the controller can be connected (e.g., via wired or network connections) to systems of a data center, and can communicate through one or more protocols. For example, the controller can communicate through one or more of an Ethernet, a web interface, a simple network management protocol (SNMP), a Modbus protocol, a transmission control protocol (TCP), a Modbus TCP protocol, a Modbus remote terminal unit (RTU) protocol, a Redfish protocol, etc. In the illustrated example, the controller 140 is shown partially removed from the rear-door cooling unit 100, while FIG. 6 illustrate the controller 140 in a fully installed position (e.g., fully inserted into the rear-door cooling unit 100).

As illustrated, the rear-door cooling unit 100 can include an interface 141. The interface 141 can comprise a touchscreen display to display information to an operator. In some cases, the touchscreen display can receive an input from an operators to control operation of the rear-door cooling unit 100. In some cases, the interface 141 can be a 7-inch touch panel display. An operator can engage the interface 141 to view information about the rear-door cooling unit 100 (e.g., temperatures, pressures, flow rates, uptime, alerts, failures of components, etc.), and can provide input at the interface 141 to control an operation of the rear-door cooling unit 100 (e.g., to select an operating mode, to define a desired cooling rate, to power the rear-door cooling unit on or off, etc.). The interface 141 can be in communication with the controller 140 and can display information received from the controller, and communicate commands from a user to the controller. In some cases, a height of the interface 141 can be selected to allow the interface to be accessible to a variety of users, including, for example, disabled operators. For example, the height of the interface 141 can adhere to standards of the Americans with Disabilities Act (“ADA”), and can be positioned at between about 686 mm to about 2032 mm from a floor surface in a vertical direction. In some cases, a height of the interface can be selected to allow an operator to comfortably engage the interface while seated (e.g., in a wheelchair). In some cases, a rear-door cooling unit can be accessible from other interfaces additionally or alternatively to a touch screen panel. For example, in some cases, a controller can provide a web interface (e.g., a web page or an application programming interface) to allow a remote control of the rear-door cooling unit. In some cases, a controller can include interface ports (e.g., USB ports, ethernet ports, etc.) as can allow a user to perform a wired connection to the controller to gain information or provide commands to the controller. In some cases, a rear-door cooling unit does not have a panel interface, as can provide more space for additional fan assemblies.

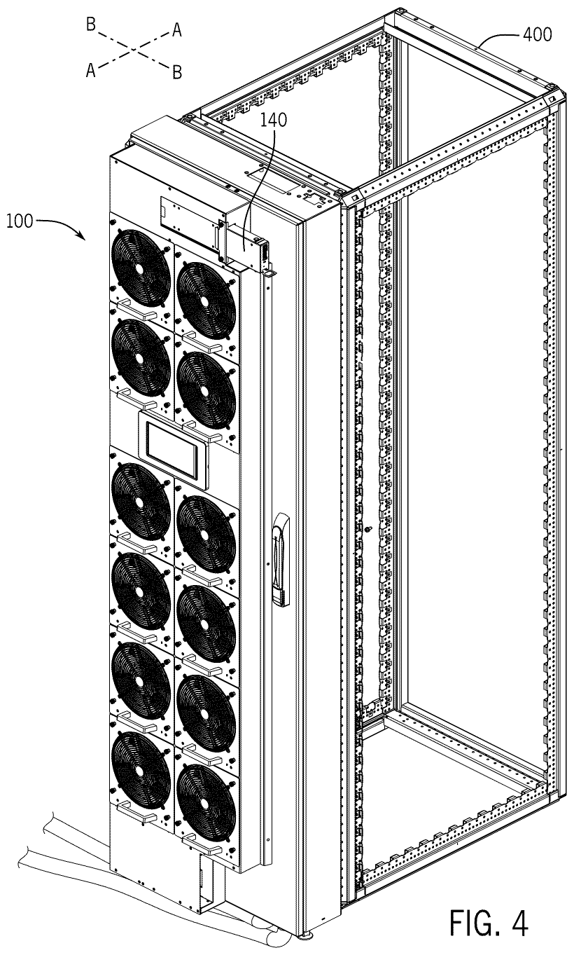

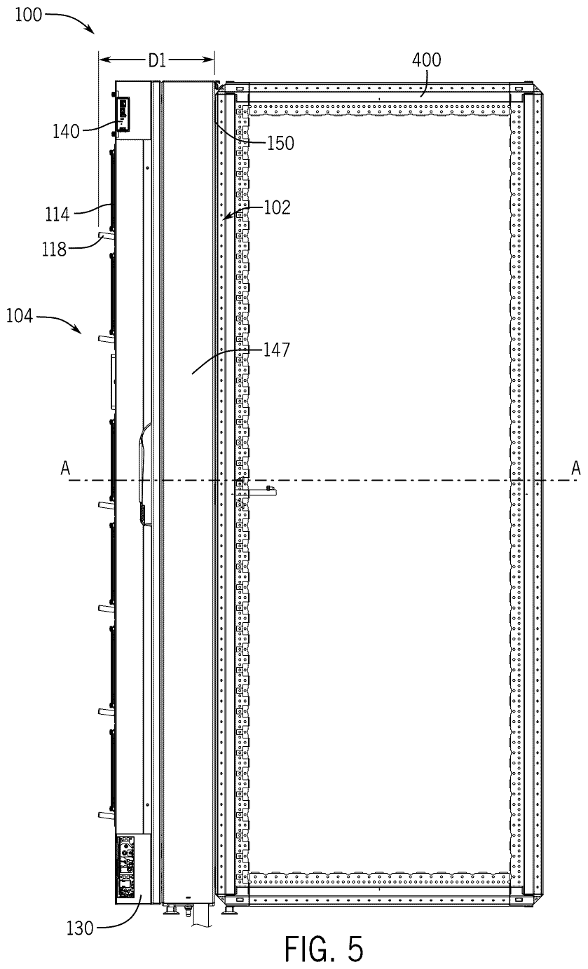

FIG. 4 illustrates the rear-door cooling unit 100 mounted on an enclosure frame 400, which can be an enclosure frame housing electrical equipment to be cooling by the rear-door cooling unit 100. As shown, the rear-door cooling unit 100 can increase a total footprint (e.g., an amount of floor space in a data center required for a rack of electrical equipment) by adding to the depth of the enclosure frame 400. In some cases, it can be advantageous to minimize a total depth of a rack (e.g., an enclosure frame) and associated rear-door cooling unit (e.g., in the direction of axis A, the depth measured in a direction parallel to a direction between aisles of a data center), due to space constraints within a data center, to increase an aisle width, etc. Embodiments of the rear-door cooling units disclosed herein can advantageously reduce a depth required for a rear-door cooling unit, including by providing for lateral installation and maintenance of components (e.g., in a direction parallel to axis B). In this regard, FIG. 4 illustrates the controller 140 partially removed from the unit 100, in a lateral direction, parallel to axis B. As shown, removing the controller 140 does not require additional clearance for the rear-door cooling unit 100 in the depth direction parallel to axis A. Further, as shown, the controller 140 and power supply units 132a, 132b (e.g., as shown in FIG. 2) are elongate in a lateral direction, parallel direction to axis B, so that a total depth of the rear-door cooling unit 100 does not need to accommodate the elongate dimension of these components. For example, FIG. 5 is a side elevation view of the rear-door cooling unit 100 mounted to the enclosure frame 400. As shown, the rear-door cooling unit extends from the enclosure frame 400 by a depth D1 in a direction parallel to the axis A. The depth D1 can be defined as a maximum distance between an element at the internal portion 102 and an element of the external portion 104. For example, as shown in FIG. 5 and FIG. 8, a depth of a rear-door cooling unit (e.g., the depth D1) can be defined as a distance between a surface 150 facing a rack (e.g., in contact with the frame 400), and a distal surface of a handle 118 of a fan assembly 114. In some cases, the depth D1 can be smaller than a total length of the controller 140 in an elongate direction of the controller 140. In some cases, the depth D1 can be less than or equal to 250 mm. In some cases, the total depth D1 of the rear-door cooling unit 100 can be between about 200 mm and about 250 mm.

FIG. 6 is a front elevation view of the rear-door cooling unit 100. As shown, the rear-door cooling unit can have a width D2 in a direction parallel to the B axis. The width can be a total distance between the first lateral surface 146 and the second lateral surface 147. In some cases, the width D2 can be a standard width of a rack within a data center. For example, the width D2 can be about 600 mm or less than about 600 mm. In the illustrated embodiment, the front face 144 of the controller 140 can extend to a width D3 from the first lateral surface 146 (e.g., a lateral surface at the hinge side 110 of the rear-door cooling unit) of the rear-door cooling unit 100 in a direction parallel to the axis B. A difference between the width D2 and the width D3 can be sufficient to remove the controller 140 in a direction along the B axis without the face 144 of the controller 140 extending past the rear-door cooling unit 100. In some cases, the difference between the width D2 and the width D3 is greater than a length of the controller 140. In some cases, the housing 130 can extend to a width D4 in a direction along the B axis from the lateral surface 146. A difference between the width D4 and the width D2 can be greater than or equal to an elongate length of one or both of the power supply units 132a, 132b. The width D4 can be sufficient to allow the power supply units 132a, 132b to be removed or installed without extending past the rear-door cooling unit 100 (e.g., extending past the lateral surface 147).

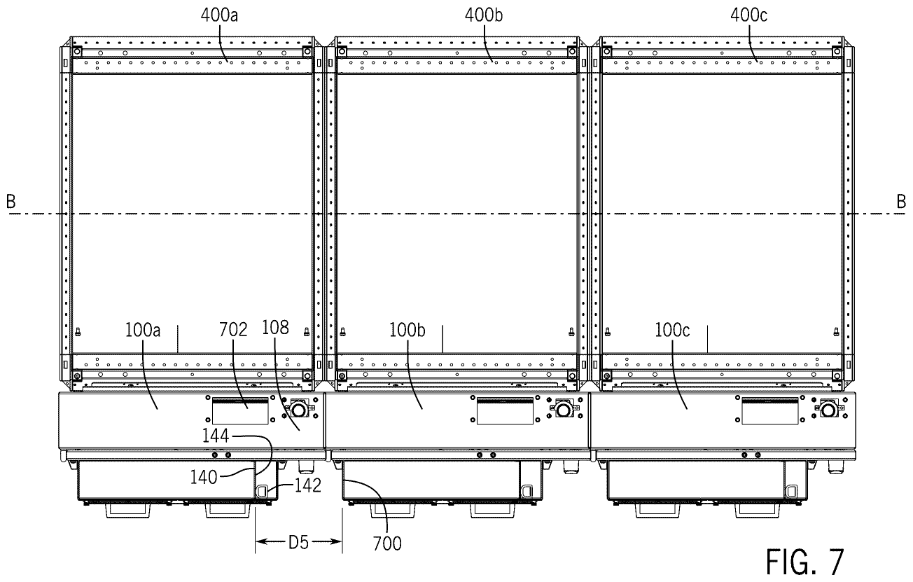

Racks can be arranged in a row within a data center. FIG. 7 illustrates enclosure frames 400a, 400b, 400c arranged consecutively in a row, with enclosure frame 400a on a first lateral side of enclosure frame 400b, and enclosure frame 400c on a second lateral side of enclosure frame 400b. Each of the enclosure frames 400a, 400b, 400c, has an associated rear-door cooling unit 100a, 100b, 100c. As shown, the rear-door cooling units 100a, 100b, 100c, are adjacent to each other. A surface 700 of the rear-door cooling unit 100b can oppose the front face 144 of the controller 140 of the rear-door cooling unit 100a, and can be spaced apart from the front face 144 by a distance of D5 when the controller 140 is installed. The distance D5 can be configured to allow removal of the controller 140. For example, the distance D5 can be greater than an elongate length of the controller 140 so that the controller 140 can be removed from the rear-door cooling unit 100a without contacting the surface 700. Similarly, the distance D4 (e.g., shown in FIG. 6) can be configured to allow the power supply units 132a, 132b to be removed without abutting an opposing surface of an adjacent rear-door cooling unit. FIG. 7 further illustrates apertures 702 in a top of the rear-door cooling units 100a, 100b, 100c to allow hosing to enter a top of the respective units 100a, 100b, 100c in a top feed configuration. As shown the apertures 702 are at a first lateral side 108 of the respective units 100a, 100b, 100c. In some cases, a condensate pump can be provided in the rear-door cooling unit, to prevent condensation in the unit which may damage components of the unit when the hosing is in a top feed configuration. In some cases, leak detection systems can be provided in a rear-door cooling unit.

FIG. 9 illustrates an inside of the housing 130 of the rear-door cooling unit 100. As shown, the housing 130 can include a first bay 900a sized and configured to receive a first power supply unit (e.g., power supply unit 132a) and a second bay 900b sized and configured to receive a second power supply unit (e.g., power supply unit 132b). The bays 900a, 900b can be separated and at least partially defined by a divider 902. In some cases, a housing for power supply units can include only one bay, or more than two bays. As further shown, each bay 900a, 900b can include blind mate connections 904a, 904b respectively. The blind mate connections 904a, 904b can include power supply connections for an AC power supply input and a DC power supply output. The blind mate connections 904a, 904b can also include communication interfaces to operatively connect the power supplies to a controller (e.g., the controller 140) to control modes of operation of the power supply units, or to receive operating parameters therefrom. In the illustrated example, the bays 900a, 900b are stacked vertically. In other examples, bays 900a, 900b can be at a same vertical height from the floor, and can be arranged side-by-side.

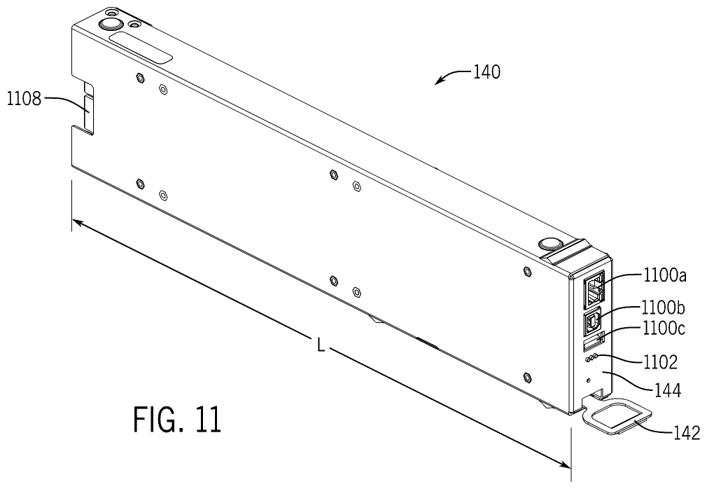

FIG. 11 is an isometric view of the controller 140, according to some embodiments. As shown, the controller 140 can include one or more interfaces 1100a, 1100b, 1100c (e.g., ports) for wired connections to the controller 140. In some cases, the interfaces can include one or more USB interfaces, an ethernet interface, a Modbus interface, etc. The controller 140 can include visual indicators 1102 (e.g., LEDs) for providing a visual indication of an operational state of the controller 140. Further, the controller 140 can include blind mate connections 1108 at a back therefore to automatically connect the controller to communication systems and power supply of the rear-door cooling unit (e.g., the rear-door cooling unit 100) when the controller 140 is installed in the rear-door cooling unit 100. The controller 140 can define a length L in an elongate direction of the controller 140, which can be configured to allow removal and installation of the controller 140 in a rear-door cooling unit 100 without the need to open the rear-door cooling unit 100 or otherwise interrupt a cooling operation of the rear-door cooling unit 100. For example, the length L can be smaller than one or both of the difference between distance D3 and D2 shown in FIG. 6, and the distance D5 shown in FIG. 7.

FIG. 12 illustrates a rear of the rear-door cooling unit 100, showing components along the internal portion 102 of the rear-door cooling unit 100. As shown, a liquid-to-air heat exchanger 1200 can be provided within the rear-door cooling unit 100. The liquid-to-air heat exchanger 1200 can be a high-performance heat exchanger with vertical fins and hydrophilic coating. In some cases, a heated liquid coolant from the electrical equipment can flow into the heat exchanger 1200, and heat of the heated liquid coolant can be transfers to an air surrounding the heat exchanger 1200. Cooled liquid coolant from the heat exchanger 1200 can flow back to the electrical equipment to cool the electrical equipment. As shown a panel 1201 can be provided at a side of the heat exchanger 1200 proximate a rack. The panel 1201 can include venting, apertures, or louvres to allow an air flow therethrough. In some cases, an air filter can be provided for the heat exchanger 1200 (e.g., between the heat exchanger 1200 and the panel 1201).

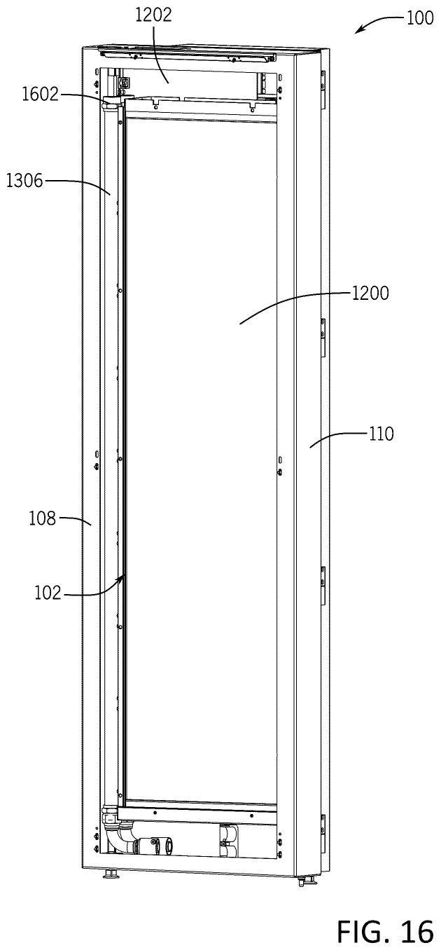

As shown, the rear-door cooling unit can provide a hosing compartment 1202 above the heat exchanger 1200 for housing hosing entering the rear-door cooling unit 100 in a top feed configuration (e.g., through the apertures 702). Quick-connect hydraulic fittings (e.g., quick-connect fittings 1602 shown in FIG. 16) can be provided in a top of the rear-door cooling unit 100 to fluidly connect hosing entering from a top feed to the heat exchanger 1200. In the illustrated embodiment, hosing 120, 122 enters in a bottom feed configuration, and a removable panel 1204 is provided to cover the hosing 120, 122. Further, a condensate tray 1206 can be provided in a bottom of the rear-door cooling unit 100 to receive any condensation and leaked fluid. In some cases, a condensate pump can be provided.

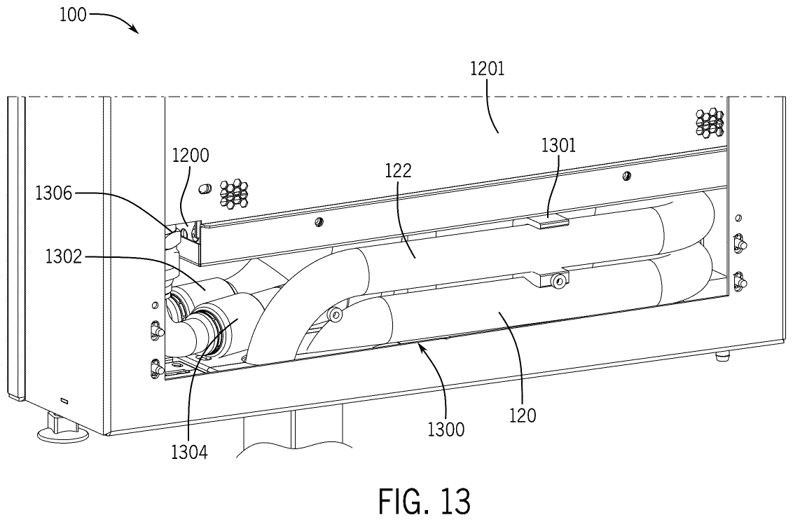

FIG. 13 illustrates a bottom of the rear-door cooling unit 100 with the panel 1204 removed to show the return line hosing 120 and the supply line hosing 122 arranged in the bottom compartment 1300 of the rear-door cooling unit 100. As shown, the bottom compartment 1300, and thus the hosing 120, 122 is beneath the heat exchanger 1200. This arrangement can be advantageous, as in the illustrated configuration, no hosing of the supply or return line hosing 120, 122 is positioned within an air flow path (e.g., along a front or rear surface of 1200 heat exchanger 1200), thus increasing a cooling efficiency of the rear-door cooling unit 100. Further, the arrangement shown can advantageously improve over some conventional systems, as swivel mechanisms are not required for the hosing 120, 122 to maintain the hosing in place, and allow for the opening and closing of the rear-door cooling unit 100 without negatively displacing the hosing 120, 122. As shown, brackets 1301 can be provided within the bottom compartment 1300 to retain the hosing 120, 122 in a desired position within the bottom compartment 1300. In other embodiments, hosing (e.g., hosing 120, 122) can enter the rear-door cooling unit 100 in a top feed configuration, and can be housed in compartment 1202 (e.g., illustrated in FIG. 12) to keep the hosing from entering an air flow path of air flow across the heat exchanger 1200. As shown, hydraulic quick-connect fittings 1302, 1304 can be provided to connect hosing 120, 122 to a fluid outlet and fluid inlet respectively of the heat exchanger 1200. The hosing 120, 122 can be installed and removed toollessly by connecting quick-connect fittings of the hosing 120, 122 with the hydraulic quick-connect fittings 1302, 1304. As shown, the quick connect fittings 1302, 1304 are positioned at the first lateral side 108, opposite the hinge side (e.g., closer to lateral surface 147 than to lateral surface 146). The quick-connect fittings 1302, 1304 comprise elbow joints, positioning the fittings 1302, 1304 at an angle relative to headers 1306 of the heat exchanger 1200. In the illustrated example, the fittings 1302, 1304 are positioned at a 90-degree angle relative to the headers of the heat exchanger 1200. In some cases, the fittings 1302, 1304 can swivel relative to the corresponding headers 1306, as can facilitate an case of installation and connection. As shown in FIG. 16, the headers 1306 can comprise elongate tubes on the first lateral side 108 of the rear-door cooling unit 100 and can provide coolant from the return line hosing 120 to the heat exchanger 1200 and provide coolant from the heat exchanger 1200 to the supply line hosing 122.

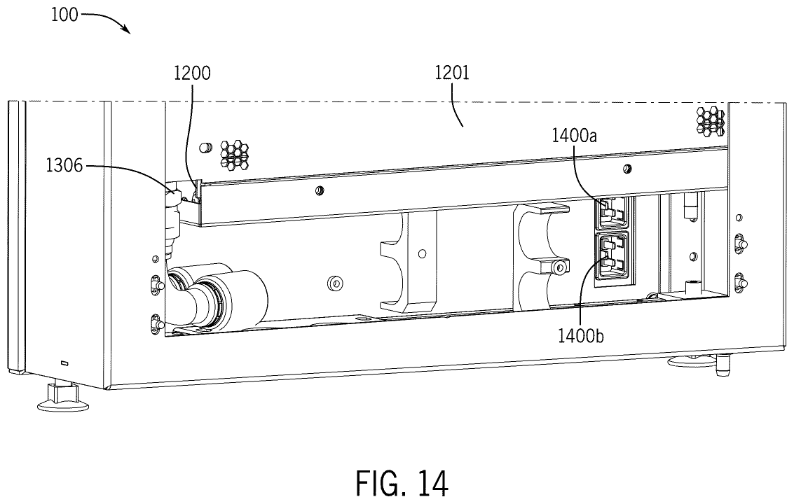

FIG. 14 illustrates a bottom of the rear-door cooling unit 100 showing the bottom compartment 1300 with the hosing 120, 122 removed. As shown, electrical connections 1400a, 1400b can be provided within the compartment 1300 to receive power from power cords of a facility. Each of the electrical connections 1400a, 1400b can provide power to a corresponding power supply unit 132 in a corresponding bay 900a, 900b of the housing 130.

FIG. 15 illustrates a control system 1500 for a rear-door cooling unit (e.g., rear-door cooling units 100, 200) described above. As shown, the control system 1500 can include one or more fan modules 1502 (e.g., one or more of the fan assemblies 114 shown in FIG. 15), sensing components 1504, a flow control valve 1510 (e.g., valve 128 shown in FIG. 2), and a controller 1506 (e.g., the controller 140). Any or all of the fan modules 1502, the controller 1506, and the sensing components 1504 can receive DC power from power supply units 1508a, 1508b (e.g., power supply units 132a, 132b shown in FIG. 2 and power supply units 232a, 232b shown in FIG. 3). The sensing components of the control system 1500 can include temperature sensors, pressure sensors, flow sensors, humidity sensors, differential temperature sensors, differential pressure sensors, or other know sensor types. The sensing components 1504 can sense parameters of an air, or a fluid of a rear-door cooling unit. For purposes of illustration, only one Fan Module 1502 is shown, however, it is to be understood that the control system 1500 can include any number of fan modules and associated fans, including, for example, 12 fans, as shown and described with respect to FIG. 2.

As illustrated, the fan module 1502 can include a fan controller, which can provide local controls for an individual fan module. The fan module 1502 can further include a fan motor which can include a fan speed sensor, a Humidity Sensor, and a Temperature Sensor. Each of the Fan Speed Sensor, Humidity Sensor, and Temperature Sensor can provide measurements for a sensed value to the Fan Controller. The Fan Motor, as shown, which can receive a signal from the Fan Controller to drive an operation of the Fan Motor. As further shown, the Fan Controller can be in communication with the Controller 1506. In normal operation of the control system 1500, the Controller 1506 can provide sensed values from any of the described sensors to the Controller 1506 and can receive a signal from the Controller 1506 to drive operation of the Fan Motor. In other cases, including when a communication between the Fan Module and the Controller 1506 is interrupted, the Fan Controller can autonomously control a speed of the Fan Motor, according to instructions preprogrammed in the Fan Controller. In some examples, when a fan controller is autonomously driving a fan motor, it can operate a feedback control system based on sensor parameters obtained from sensors of the fan module.

The valve 1510 can comprise a solenoid valve, and a position of the solenoid valve can be normally open or normally closed. The valve 1510 can be in communication with the Controller 1506, and can open or close in response to a signal from the controller. In some cases, the valve 1510 can define a position other than fully opened or fully closed, as can allow a restriction of flow through the valve. In some case, for example, a valve for a rear door cooling unit can comprise a servo motor to open the valve to different intervals. In some cases, a valve can be a three-way valve, and can receive a signal from a controller to place the valve in one of three predefined positions.

Referring back to FIG. 15, the Controller 1506 can be in communication with the Sensor Components 1504 to receive sensed values from sensors thereof. Sensing components 1504 can include temperature sensors, pressure sensors, flow rate sensors, humidity sensors, differential pressure sensors, differential temperature sensors, sensors to sense a motor speed of fans, position sensors of valves, etc. In an example, temperature and pressure sensors can be provided at a return line (e.g., upstream of a heat exchanger) and a supply line (e.g., downstream of a heat exchanger), and the Controller 1506 can receive values from the sensors of the supply line and the sensors of the return line to determine a differential pressure and a differential temperature across the heat exchanger.

In some examples, communication between components of the control system 1500 can be over a wired connection (e.g., a Modbus, an ethernet connection, USB connections, etc.). In some embodiments, communication between one or more elements of the control system can occur via a wireless connection (e.g., a wi-fi connection, a cellular connected, etc.).

In some embodiments, the controller 1506 can be a programmable logic controller (PLC). In some embodiments, the controller 1506 can include a processor, one or more Input/Output interfaces, a Communication System(s), and a Memory. In some embodiments, the Processor can be any suitable hardware processor or combination of processors, such as a central processing unit (CPU), a graphics processing unit (GPU), an application specific integrated circuit (ASIC), a field-programmable gate array (FPGA), etc. In some embodiments, one or more Input/Output interfaces can include any suitable display device, such as a computer monitor, a touchscreen, a television, any suitable input devices and/or sensors that can be used to receive user input, such as a keyboard, a mouse, a touchscreen, a microphone, a camera, etc. Inputs can be received at a display which can present a user interface through which an operator can view system parameters, and set control parameters (e.g., set an operating mode, define set points for temperature or pressure, set a language of the system, etc.).

In some embodiments, the Communication System(s) of the controller 1506 can include any suitable hardware, firmware, and/or software for communicating information over any suitable communication networks. For example, the Communication System(s) can include one or more transceivers, one or more communication chips and/or chip sets, etc. In a more particular example, the Communications System(s) can include hardware, firmware and/or software that can be used to establish a Wi-Fi connection, a Bluetooth connection, a cellular connection, an Ethernet connection, etc. In some embodiments, inputs can be received at the controller 1506 through the Communication System(s) (e.g., over a communication network).

In some embodiments, the Memory can include any suitable storage device or devices that can be used to store instructions, values, etc., that can be used, for example, by the Processor of the controller 1506 to implement control loops and algorithms, to store logs of the controller 1506, etc. The Memory can include any suitable volatile memory, non-volatile memory, storage, or any suitable combination thereof. For example, the Memory can include random access memory (RAM), read-only memory (ROM), electronically-erasable programmable read-only memory (EEPROM), one or more flash drives, one or more hard disks, one or more solid state drives, one or more optical drives, etc. In some embodiments, the Memory can have encoded thereon a computer program for controlling operation of the Controller 1506.

As further shown, the electrical components of the rear-door cooling unit 100 can receive a power (depicted in a dashed line) from one or both of the Power Supply Units 1508a, 1508b. The Power Supply Units 1508a, 1508b can further be in electrical communication with the Controller 1506. For example, the Power Supply Units 1508a, 1508b can communicate a status to the Controller 1506 (e.g., via a Modbus connection). In some cases, the Controller 1506 can provide a signal to the Power Supply Units 1508a, 1508b to control an operation of the Power Supply Units 1508a, 1508b. For example, a signal from the Controller 1506 can initiate a failover from the Power Supply Unit 1508a to the Power Supply Unit 1508b. The Controller 1506 can control an operating mode (e.g., active-standby, active-active, active-passive, etc.) of the Power Supply Units 1508a, 1508b.

In some cases, a rear-door cooling unit can be provided for 42U racks. In some cases, rear-door cooling units can be provided for 47U racks. The table below illustrates a configuration and associated performance metrics obtained in testing of a rear-door cooling unit (e.g., the cooling unit 100 described above).

| Number of Fans | 12 | |
|---|---|---|
| Air Flow | 12.00 | m³/h |
| Water Flow | 6.0 | m³/h |
| Water Pressure Drop at Full Flow | 1 | bar |
| Performance (14° C. water supply, | 85 | kW |
| 24° C. air supply) | | |
| Performance (20° C. water supply, | 48 | kW |
| 24° C. air supply) | | |
| Performance (24° C. water supply, | 39 | kW |
| 27° C. air supply) | | |
| Power Consumption | 1500 | W |

The previous description of the disclosed embodiments is provided to enable any person skilled in the art to make or use the invention. Various modifications to these embodiments will be readily apparent to those skilled in the art, and the generic principles defined herein may be applied to other embodiments without departing from the spirit or scope of the invention. Thus, the invention is not intended to be limited to the embodiments shown herein but is to be accorded the widest scope consistent with the principles and novel features disclosed herein.

1. A cooling system for electrical equipment comprising:
a rack;
a rear-door cooling unit mounted to the rack, the rear-door cooling unit being pivotable about a first axis between an open position and a closed position and defining a first side proximate the rack, and a second side opposite the first side;
a liquid-to-air heat exchanger mounted within the rear-door cooling unit;
a fan, a controller, and a power supply unit, each of the fan, the controller, and the power supply unit mounted to the rear-door cooling unit at the second side, and accessible from the second side when the rear-door cooling unit is in the closed position.

2. The cooling system of claim 1, wherein each of the fan, the controller, and the power supply unit are configured for tool less removal.

3. The cooling system of claim 1, wherein each of the fan, the controller, and the power supply unit includes a blind mate connector that engages a corresponding blind mate connector of the rear-door cooling unit.

4. The cooling system of claim 1, wherein the rear-door cooling unit includes a hinge at a first lateral side of the rear-door cooling unit, the hinge at least partially defining the first axis.

5. The cooling system of claim 4, wherein the liquid-to-air heat exchanger includes a supply header and a return header, wherein each of the supply header and the return header are positioned at a second lateral side of the rear-door cooling unit, opposite the first lateral side, each of the supply header and the return header including a quick disconnect fitting.

6. The cooling system of claim 5, wherein the rear-door cooling unit includes apertures configured to receive hosing in a bottom feed configuration.

7. The cooling system of claim 1, wherein the power supply unit is one of a plurality of power supply units.

8. The cooling system of claim 1, wherein the fan is one of a plurality of fans, each of the plurality of fans mounted to the rear-door cooling unit at the second side.

9. The cooling system of claim 1, wherein each of the fan, the controller, and the power supply unit are hot swappable.

10. The cooling system of claim 1, wherein a second axis extends through the first side and the second side, and wherein a maximum depth of the rear-door cooling unit in a direction parallel to the second axis is between about 200 mm and about 250 mm.

11. The cooling system of claim 1, wherein a lateral axis is defined between opposing lateral sides of the rear-door cooling unit, wherein the controller is configured for removal from the rear-door cooling unit in a direction parallel to the lateral axis.

12. The cooling system of claim 9, wherein the power supply unit is configured for removal from the rear-door cooling unit in a direction parallel to the lateral axis.

13. A cooling system comprising:
a rear-door cooling unit including:
a first lateral portion including a first lateral surface;
a second lateral portion opposite the first lateral portion, the second lateral portion including a second lateral surface, the second lateral surface being parallel to the first lateral surface and a lateral axis being defined between the first lateral surface and the second lateral surface;
a heat exchanger including a supply port and a return port, both of the supply port and the return port positioned within the second lateral portion;
a fan assembly defining a fan rotation axis, the fan rotation axis being perpendicular to the lateral axis;
a removable controller insertable into the rear-door cooling system in an insertion direction that is parallel to the lateral axis; and
a first power supply unit insertable into the rear-door cooling unit in a direction that is parallel to the lateral axis.

14. The cooling system of claim 13, wherein the rear-door cooling unit defines an internal portion and an external portion opposite the internal portion, wherein each of the fan assembly, the removable controller, and the power supply unit is mounted at the external portion.

15. The cooling system of claim 14, further comprising a rack, wherein the rear-door cooling unit is mounted to the rack, with the internal portion facing the rack, and the external portion facing away from the rack.

16. The cooling system of claim 15, wherein the rear-door cooling unit is configured to rotate relative to the rack between an open position and a closed position, wherein the fan assembly, the removable controller, and the power supply unit are accessible from an exterior of the rack in both of the open and closed position.

17. The cooling system of claim 13, wherein a depth direction is perpendicular to the lateral axis, wherein a maximum depth of the rear-door cooling unit is between about 200 mm and about 250 mm.

18. The cooling system of claim 13, further comprising a second power supply unit, wherein the first and second power supply units are configured for tool less removal from the rear-door cooling unit.

19. The cooling system of claim 13, wherein the removable controller is configured for tool less removal from the rear-door cooling unit.

20. A method of cooling electrical equipment including:
providing a rack;
mounting a rear-door cooling unit to the rack, the rear-door cooling unit being pivotable about a first axis between an open position and a closed position and defining a first side proximate the rack, and a second side opposite the first side;
mounting a liquid-to-air heat exchanger within the rear-door cooling unit;
inserting a fan, a controller, and a power supply unit into the rear-door cooling unit, each of the fan, the controller, and the power supply unit mounted to the rear-door cooling unit at the second side, and accessible from the second side when the rear-door cooling unit is in the closed position;
operating a flow control valve to allow a flow of fluid through the liquid-to-air heat exchanger; and
operating the fan to produce an air flow across the heat exchanger.
